(19) United States
(12) Patent Application Publication
(10) Pub. No.: US 2026/0214933 A1
(43) Pub. Date: Jul. 23, 2026

(54) SEMICONDUCTOR DEVICE AND METHOD FOR MANUFACTURING THE SAME

(71) Applicant: Monolithic Power Systems, Inc., Kirkland, WA (US)

(72) Inventors: Ji-Hyoung Yoo, Los Gatos, CA (US); Haifeng Yang, Shanghai (CN); Yanjie Lian, Chengdu (CN); Daping Fu, Chengdu (CN)

(21) Appl. No.: 19/027,848

(22) Filed: Jan. 17, 2025

(51) Int. Cl. H10D 30/65; H10D 30/01; H10D 62/17; H10D 64/00

(52) U.S. Cl. CPC H10D 30/65; H10D 30/0281; H10D 62/393; H10D 64/111

(57) ABSTRACT

The semiconductor substrate has a source region, a drain region, a body region between the source region and the drain region, and a drift region between the body region and the drain region. The gate structure is over the body region. The first dielectric layer is over the drift region of the semiconductor substrate and surrounding the gate structure. The second dielectric layer is over the drift region of the semiconductor substrate and in contact with a top surface of the first dielectric layer. The second dielectric layer includes a material different from a material of the first dielectric layer. The contact field plate is over the drift region of the semiconductor substrate and the first dielectric layer. The contact field plate extends through the second dielectric layer and in contact with the top surface of the first dielectric layer.

### BACKGROUND

### Field of Invention

The present application relates to semiconductor devices and methods for fabricating the same.

### Description of Related Art

Field plates of various constructions have been embedded within semiconductor devices to effectively reduce the magnitude of surface electric field at a given dimension to increase the breakdown voltage. Such field plates have been used for various devices, including DMOS (Diffused Metal-Oxide-Semiconductor) transistors. They are widely used in various power management applications, including used as power switching elements in power supplies for industrial and consumer electronic devices.

### SUMMARY

According to some embodiments of the present disclosure, the semiconductor substrate has a source region, a drain region, a body region between the source region and the drain region, and a drift region between the body region and the drain region. The gate structure is over the body region. The first dielectric layer is over the drift region of the semiconductor substrate and surrounding the gate structure. The second dielectric layer is over the drift region of the semiconductor substrate and in contact with a top surface of the first dielectric layer. The second dielectric layer includes a material different from a material of the first dielectric layer. The contact field plate is over the drift region of the semiconductor substrate and the first dielectric layer. The contact field plate extends through the second dielectric layer and in contact with the top surface of the first dielectric layer.

According to some embodiments of the present disclosure, a semiconductor device includes a semiconductor substrate, a gate structure, an etch resistance layer, an interlayer dielectric layer, and a contact field plate. The semiconductor substrate has a source region, a drain region, and a drift region between the body region and the drain region and near the drain region. The gate structure is over a region of the semiconductor substrate between the source region and the drain region. The etch resistance layer is over the drift region of the semiconductor substrate. The source region and the drain region are free from coverage by the etch resistance layer. The interlayer dielectric layer is over the gate structure and the etch resistance layer. The interlayer dielectric layer comprises a material different from a material of the etch resistance layer. The contact field plate is over and spaced apart from the drift region of the semiconductor substrate. The contact field plate extends through the interlayer dielectric layer and the etch resistance layer, and the contact field plate has a bottom surface free from coverage by the etch resistance layer.

According to some embodiments of the present disclosure, a method for manufacturing a semiconductor device is provided. The method includes forming a drift region in a semiconductor substrate; forming a gate structure over the semiconductor substrate; depositing a dielectric layer over the gate structure and the semiconductor substrate; forming an etch resistance layer over the dielectric layer; depositing an interlayer dielectric layer over the etch resistance layer and the dielectric layer; performing an etch process to etch a contact opening through the interlayer dielectric layer and the etch resistance layer, wherein the opening exposes a top surface of the dielectric layer; and forming a contact field plate in the contact opening.

### BRIEF DESCRIPTION OF THE DRAWINGS

The disclosure can be more fully understood by reading the following detailed description of the embodiment, with reference made to the accompanying drawings as follows.

FIGS. 1-9 illustrate schematic cross-sectional views of intermediate stages in the manufacture of a semiconductor device in accordance with some embodiments of the present disclosure.

FIG. 10 is an example signal diagram illustrating an etch signal for etch stop detection in accordance with some embodiments of the present disclosure.

FIG. 11 illustrate a cross-sectional view of an intermediate stage in the manufacture of a semiconductor device in accordance with some embodiments of the present disclosure.

FIG. 12 illustrate a cross-sectional view of an intermediate stage in the manufacture of a semiconductor device in accordance with some embodiments of the present disclosure.

FIGS. 13-14 illustrate schematic cross-sectional views of intermediate stages in the manufacture of a semiconductor device in accordance with some embodiments of the present disclosure.

### DETAILED DESCRIPTION

Embodiments of the present invention will be described in detail below. It should be noted that the embodiments described here are only for illustration and are not intended to limit the present invention. In the following description, numerous specific details are set forth in order to provide a thorough understanding of the invention. However, it will be apparent to one of ordinary skill in the art that these specific details need not be employed in order to practice the invention. In other instances, well-known materials or methods have not been described in detail in order to avoid obscuring the present invention.

Some embodiments of the present disclosure relate to DMOS (Diffused Metal-Oxide-Semiconductor) transistors that are formed with a contact field plate on a drift region of a substrate.

FIGS. 1-9 illustrate schematic cross-sectional views of intermediate stages in the manufacture of a semiconductor device in accordance with some embodiments of the present disclosure. It is understood that additional steps may be provided before, during, and after the steps shown in FIGS. 1-9, and some of the steps described below can be replaced or eliminated for additional embodiments of the method. The order of the operations/processes may be interchangeable.

Reference is made to FIG. 1. A high voltage transistor device T1 is formed. The high voltage transistor device T1 includes a body region 112, a drift region 114, a source region 116, a drain region 118 within a semiconductor substrate 110 and a gate structure 120 over the semiconductor substrate 110. In some embodiments, the semiconductor substrate 110 and the body region 112 has a first conductivity type, while the drift region 114, the source region 116 and the drain region 118 have a second conductivity type opposite to the first conductivity type. The body region 112 has a higher doping concentration than a doping concentration of the semiconductor substrate 110. And, the source region 116 and the drain region 118 have a higher doping concentration than a doping concentration of the drift region 114. In some embodiments, the first conductivity type may by an n-type conductivity and the second conductivity type may be a p-type conductivity. In some alternative embodiments, the first conductivity type may by a p-type conductivity and the second conductivity type may be an n-type conductivity.

The gate structure 120 is laterally arranged between the source region 116 and the drain region 118. In some embodiments, the gate structure 120 may overlap the body region 112 and a portion of the drift region 114. The gate structure 120 includes a gate dielectric 122 and a gate electrode 124 over the gate dielectric 122. Upon receiving a bias voltage, the gate electrode 124 is configured to generate an electric field that controls the movement of charge carriers within a channel region in the semiconductor substrate 110 laterally disposed between the source region 116 and the drift region 114. For example, during operation, a gate-source voltage (Vgs) can be selectively applied to the gate electrode 124 relative to the source region 116 forming a conductive channel in the body region 112. The drift region 114 may provide a higher resistance at high operating voltages.

A contact region 119 having the first conductivity type laterally abuts the source region 112. The contact region 119 provides for an ohmic connection to the semiconductor substrate 110. The contact region 119 and the source region 118 are disposed within the body region 112.

Formation of the high voltage transistor device T1 may include a body implantation process for forming the body region 112, a drift implantation process for forming the drift region 114, and an oxide formation process after the drift implantation process. The oxide formation process may form diffusion oxide in the drift region 114 and shallow trench isolations (STI) that defines active regions in the semiconductor substrate 110. Subsequently, the gate structure 120 is formed by depositing a gate dielectric layer over the semiconductor substrate 110, depositing a gate electrode layer (e.g., polysilicon layer) over the gate dielectric layer, and patterning the gate electrode layer and the gate dielectric layer into the gate electrode 124 and the gate dielectric 122, respectively. The patterning process may include a lithography process to form a photoresist mask over the gate electrode layer and an etching process to etch away portions of the gate electrode layer and the gate dielectric layer uncovered by the photoresist mask. Remaining portions of the gate electrode layer and the gate dielectric layer forms the gate electrode 124 and the gate dielectric 122 of the gate structure 120.

In some embodiments, after the formation of the gate structure 120, a lightly doped region having the second conductivity type may be formed in the semiconductor substrate 110 adjacent a source side where the source region 116 is to be formed, for example, by forming implantation masks (e.g., photoresist masks) and implanting dopants having the second conductivity type through the implantation masks. The lightly doped region having the second conductivity type can be used for a source of the high voltage transistor device T1. Prior to the formation of the lightly doped region(s), an oxide regrow process may be performed to form a surface oxide layer wrapping the exposed sidewall(s) of the gate electrode 124 and the silicon surface.

After the formation of the gate structure 120, gate spacers 130 may be formed on opposite sidewalls of the gate structure 120. The gate spacers 130 may include silicon nitride.

After the formation of the gate spacers 130, the source region 116 and the drain region 118 may be formed in the semiconductor substrate 110, for example, by forming implantation masks (e.g., photoresist masks) and implanting dopants having the second conductivity type through the implantation masks. And, the contact region 119 may be formed in the semiconductor substrate 110, for example, by forming implantation masks (e.g., photoresist masks) and implanting dopants having the first conductivity type through the implantation masks.

After the formation of the source region 116, the drain region 118, and the contact region 119, a salicidation process is performed. The salicidation process may include depositing a metal layer (e.g., a nickel layer or a cobalt layer) over the source region 116, the drain region 118, and the contact region 119 and the gate electrode 124. Then, the metal layer is annealed such that the metal layer reacts with silicon (and germanium if present) in the source region 116, the drain region 118, and the contact region 119 and the gate electrode 124 to form the metal salicide layers 142, 144, and 146. The non-reacted portions of the metal layer may be removed thereafter. Prior to the salicidation process, a salicide block layer 152 may be deposited and patterned to expose the source region 116, the drain region 118, and the contact region 119, thereby protecting some surfaces/structures from the metal depositions. The salicide block layer 152 may include one or more silicon oxide layers. The patterning process may include a lithography process to form a photoresist mask over the salicide block layer and an etching process to etch away portions of the salicide block layer uncovered by the photoresist mask.

Various implantation steps are performed to form a plurality of implantation regions (e.g., well regions, contact regions, etc.) in the semiconductor substrate 110. For example, the semiconductor substrate 110 may be selectively implanted to form the body region 112, the drift region 114, the source region 116, the drain region 118, and the contact region 119. The plurality of implantation regions may be formed by selectively masking the semiconductor substrate 110 (e.g., using a photoresist mask) and then introducing p-type dopants such as boron or n-type dopants such as phosphorous into exposed areas of the semiconductor substrate 110.

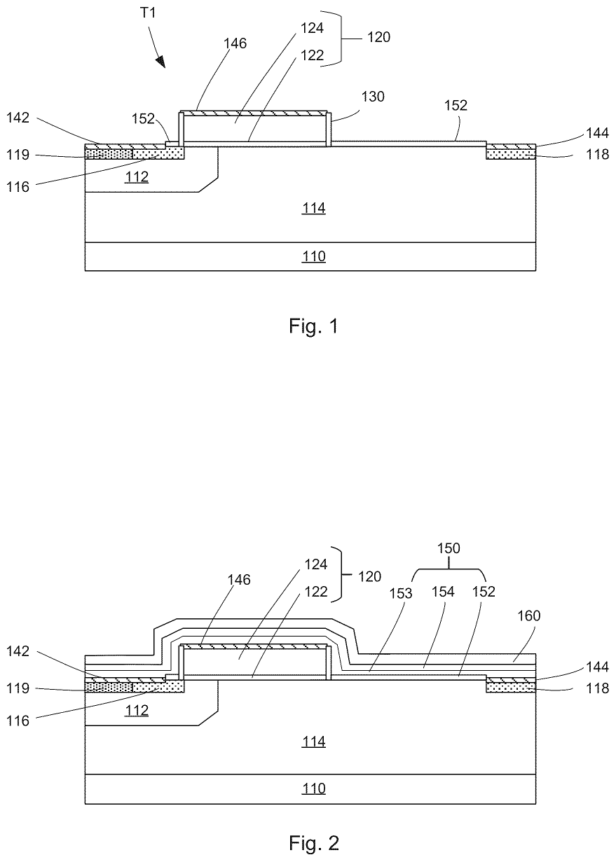

Reference is made to FIG. 2. A dielectric layer 154 is deposited over the structure of FIG. 1. The dielectric layer 154 may include silicon oxides, tetraethoxysilane (TEOS) oxide, SiOC, the like, or combinations thereof. The dielectric layer 154 may cover the gate structure 120, the drift region 114, the source region 116, the drain region 118, and the contact region 119. In some embodiments, prior to the deposition of the dielectric layer 154, a contact etch stop layer 153 is conformally deposited over the structure of FIG. 1. The contact etch stop layer 153 may include a dielectric material different from the dielectric layer 154, thereby showing etch selectivity in a following contact etch process. For example, the contact etch stop layer 153 may include silicon nitride (such as UV-transparent silicon nitride), silicon oxynitride, the like, or the combination thereof. Through the steps, a multi-film dielectric layer 150 including the salicide block layer 152, the contact etch stop layer 153, and the dielectric layer 154 is formed. In some alternative embodiments, the contact etch stop layer 153 is omitted, and the multi-film dielectric layer 150 includes the salicide block layer 152 and the dielectric layer 154.

After the deposition of the dielectric layer 154, a contact etch resistance film 160 is conformally deposited over the dielectric layer 154. The contact etch resistance film 160 may include a material different from the dielectric layer 154, thereby showing etch selectivity in the following contact etch process. The contact etch resistance film 160 may include a dielectric material (e.g., silicon nitride, silicon oxynitride) or a non-dielectric material (e.g., polysilicon). For example, while the dielectric layer 154 include silicon oxides or TEOS oxide, the contact etch resistance film 160 may include silicon nitride, silicon oxynitride, the like, or the combination thereof. In some embodiments, the contact etch resistance film 160 has a higher k value than the dielectric layer 154. For example, the dielectric layer 154 comprises a low-k dielectric material, while the contact etch resistance film 160 comprises a high-k dielectric material. In the context, the k value is referred to as a dielectric constant of a dielectric material (i.e., relative permittivity of the dielectric material).

In some embodiments, the contact etch resistance film 160 and the contact etch stop layer 153 may have higher etch resistances to the following contact etch process than silicon oxides. In such embodiments, the dielectric material of the contact etch resistance film 160 can be the same as or different from the dielectric material of the contact etch stop layer 153. In some embodiments, while the contact etch resistance film 160 and the contact etch stop layer 153 both include silicon nitride, the contact etch resistance film 160 has a thickness greater than that of the contact etch stop layer 153. For example, the thickness of the contact etch resistance film 160 may be in a range from about 500 angstroms to about 2000 angstroms, such as from about 700 angstroms to about 1700 angstroms. And, the thickness of the contact etch stop layer 153 may be in a range from about 200 angstroms to about 600 angstroms.

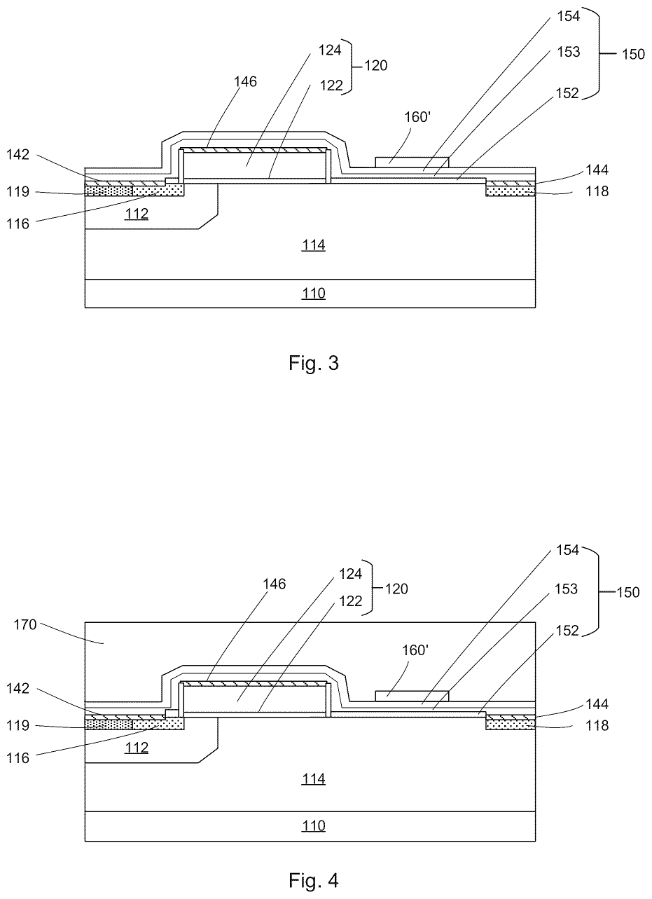

Reference is made to FIG. 3. The contact etch resistance film 160 (referring to FIG. 2) is patterned into a contact etch resistance layer 160′, which overlaps a portion of the drift region 114 and uncovers the metal salicide layer 142 over the source region 116 and the contact region 119, the metal salicide layer 144 over the drain region 118, and the metal salicide layer 146 over the gate electrode 124. The patterning process may include a lithography process to form a photoresist mask over the contact etch resistance film 160 (referring to FIG. 2) and an etching process to etch away portions of the contact etch resistance film 160 (referring to FIG. 2) uncovered by the photoresist mask. A remaining portion of the contact etch resistance film 160 (referring to FIG. 2) forms the contact etch resistance layer 160′.

After the patterning process, the gate structure 120, the source region 116, the drain region 118, and the contact region 119 are free from coverage by the contact etch resistance layer 160′. In some embodiments, the contact etch resistance layer 160′ has at least a portion over the drift region 114 and laterally aligned with the gate structure 120. In some embodiments, the portion of the contact etch resistance layer 160′ over the drift region 114 has a top surface lower than a top surface of the gate structure 120 and a bottom surface higher than a bottom surface of the gate structure 120. After the patterning process, the dielectric layer 154 may extend beyond opposite sidewalls of the contact etch resistance layer 160′.

Reference is made to FIG. 4. An interlayer dielectric (ILD) layer 170 is deposited over the structure of FIG. 3. The ILD layer 170 may include a dielectric material different from the contact etch resistance film 160. For example, the ILD layer 170 may include an oxide (e.g., SiO₂), an ultra-low k dielectric material, a low-k dielectric material (e.g., SiCO), the like, or combinations thereof. In some embodiments, the ILD layer 170 may include plural TEOS oxide layers stacked on over another. In some embodiments, the contact etch resistance film 160 has a higher k value than the ILD layer 170. For example, the ILD layer 170 comprises a low-k dielectric material, while the contact etch resistance film 160 comprises a high-k dielectric material.

After the deposition of the ILD layer 170, a chemical mechanical polish (CMP) process is then performed to planarize a top surface of the ILD layer 170. After the CMP process, the top surface of the ILD layer 170 is higher than the top surface of the gate structure 120 and a top surface of the multi-film dielectric layer 150.

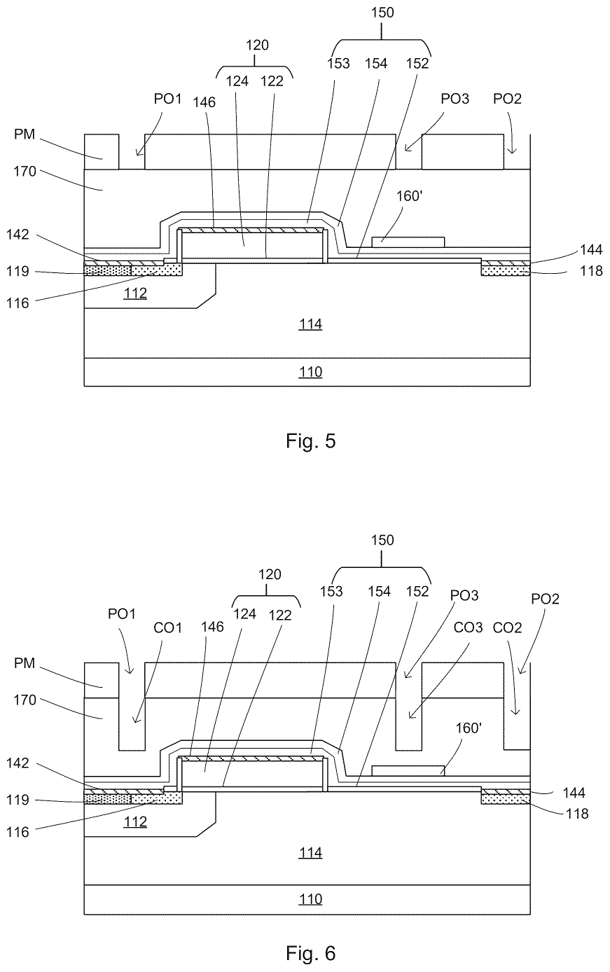

Reference is made to FIG. 5. A patterned mask PM is formed over the top surface of the ILD layer 170. In some embodiments, the patterned mask PM may be a photoresist mask formed by a photolithography process. For example, the photolithography process may include spin-on coating a photoresist layer over the top surface of the ILD layer 170, exposing the photoresist layer to patterned light, performing a post-exposure bake process, and developing the photoresist layer to form the patterned mask PM. In some embodiments, the patterned mask PM has an opening PO1 vertically overlapping the metal salicide layer 142 over the source region 116 and the contact region 119, an opening PO2 vertically overlapping the metal salicide layer 144 over the drain region 118, and an opening PO3 vertically overlapping the portion of the contact etch resistance layer 160′ over the drift region 114.

FIGS. 6-8 illustrate three stages of an etch process to form contact openings CO1-CO3 in the ILD layer 170, the contact etch resistance layer 160′, and the multi-film dielectric layer 150 using the patterned mask PM as etch mask. The three stages of the etch process in FIGS. 6-8 may use different etch recipes by tuning the composition ratios of the etchant gases introduced into the chamber of an etcher, thereby showing different etch selectivities between materials (e.g., silicon nitride and silicon oxide). The etch recipes may use chlorine-based and/or a fluorine-based gas or plasma. With the patterned mask PM in place, the etch process removes portions of layers (e.g., portions of the ILD layer 170, the contact etch resistance layer 160′, and the multi-film dielectric layer 150) exposed by the openings PO1-PO3 of the patterned mask PM, while other portions of the layers (e.g., other portions of the ILD layer 170, the contact etch resistance layer 160′, and the multi-film dielectric layer 150) are protected from being etched by the patterned mask PM. As used herein, the term “etch selectivity” refers to the ratio of the etch rates of two different materials under the same etching conditions.

FIG. 6 illustrates a first stage of the etch process where the contact openings CO1-CO3 are etched downward from the top surface of the ILD layer 170. The first stage of the etch process may use a first etch recipe that has a first etch selectivity of silicon oxide to silicon nitride greater than 1, such that the first stage of the etch process removes the ILD layer 170 at a faster etch rate than it removes the contact etch resistance layer 160′. The first stage of the etch process may be controlled by time mode, such that the first stage of the etch process is stopped when bottoms of the openings CO1-CO3 are at a level higher than the top surface of the portion of the contact etch resistance layer 160′ over the drift region 114. Since the contact openings CO1-CO3 are formed by etching the ILD layer 170 at substantially the same etch rate, the bottoms of the contact openings CO1-CO3 may be substantially laterally aligned with each other.

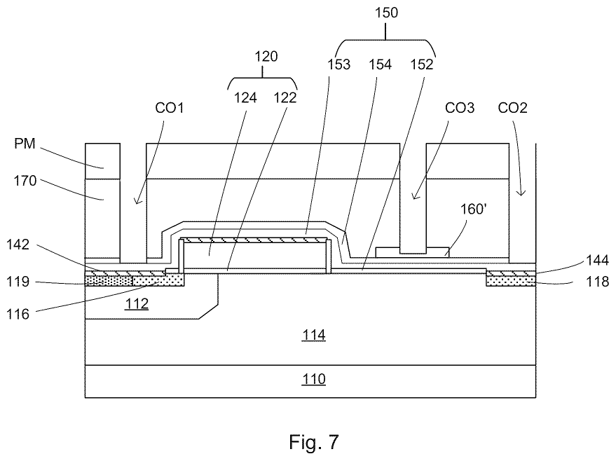

FIG. 7 illustrates a second stage of the etch process after the first stage of the etch process (referring to FIG. 6). At the second stage of the etch process, the contact openings CO1-CO3 are further deepened such that the contact etch resistance layer 160′ is exposed by the contact opening CO3, and the contact etch stop layer 153 is exposed by the contact openings CO1 and CO2. The second stage of the etch process may use a second etch recipe that has a second etch selectivity of silicon oxide to silicon nitride greater than 1, such that the etch process removes the contact etch resistance layer 160′ at a slower etch rate than it removes the dielectric layer 154 and the ILD 170. As a result, the bottoms of the contact openings CO1 and CO2 are lower than the bottom of the contact opening CO3. In some embodiments, the second etch selectivity of the second etch recipe used in the second stage of the etch process may be greater than the first etch selectivity of the first etch recipe used in the first stage of the etch process. Thus, the contact etch stop layer 153 and the contact etch resistance layer 160′ may well serve as etch stop layers.

In some embodiments, the thickness of the contact etch resistance layer 160′ is well controlled, such that the contact opening CO3 does not etch through the contact etch resistance layer 160′ when the contact openings CO1 and CO2 expose the contact etch stop layer 153. Stated differently, the contact opening CO3 is etched into a middle level in the contact etch resistance layer 160′. For example, the bottom of the contact opening CO3 is lower than a top surface of the contact etch resistance layer 160′ and higher than a bottom surface of the contact etch resistance layer 160′.

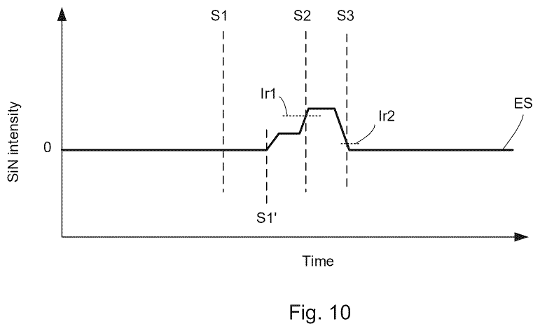

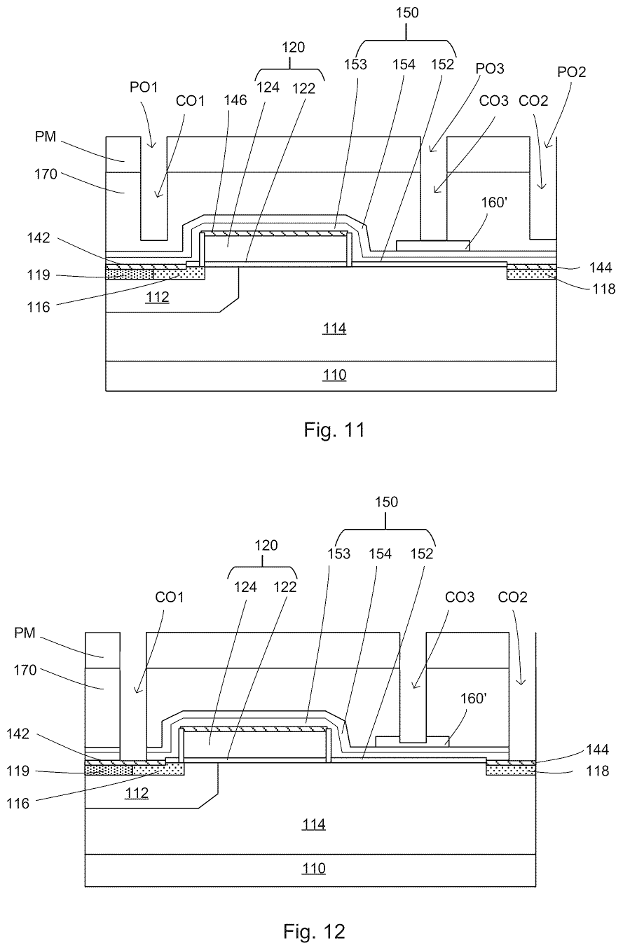

In FIG. 7, the contact openings CO1 and CO2 are not fully open yet. For example, the contact openings CO1 and CO2 extend through the dielectric layer 154 and stopped by the contact etch stop layer 153, and thus the contact openings CO1 and CO2 may not reach top surfaces of the metal salicide layers 142 and 144 therebelow. In the present embodiments, the second stage of the etch process may stop when an etch signal shows a large amount of silicon nitride (e.g., when an intensity of the material of the contact etch resistance layer 160′ of the etch signal ES is higher than a threshold intensity value Ir1, as shown later in FIG. 10). This indicates the etch stop time point that the contact etch stop layer 153 are just exposed by the contact openings CO1 and CO2. In some alternative embodiments, the contact openings CO1 and CO2 may be fully open at the second stage of the etch process, as shown in FIG. 11 later.

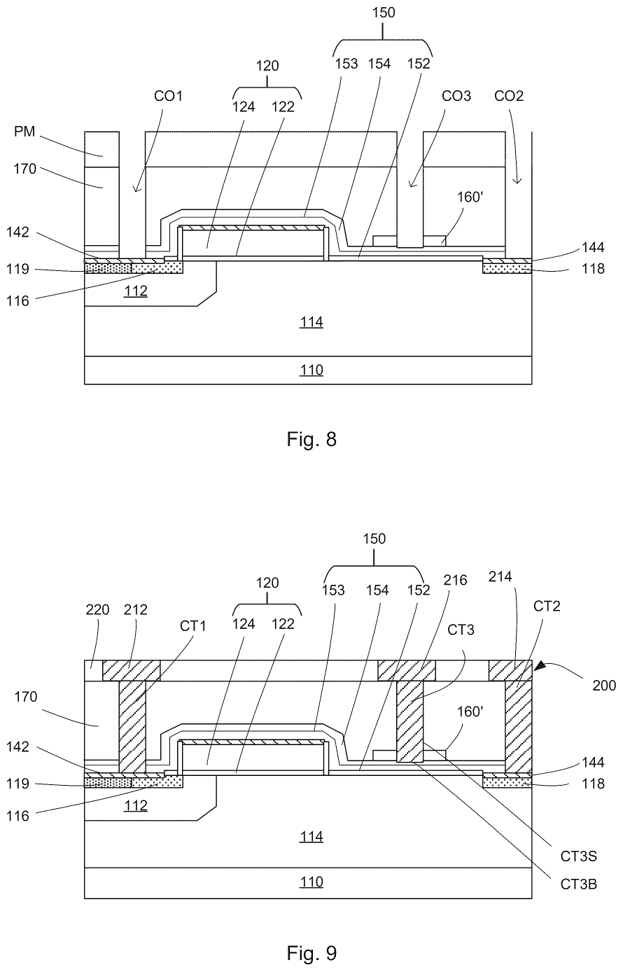

FIG. 8 illustrates the third stage of the etch process where the contact openings CO1-CO3 are further deepened such that the contact opening CO3 is etched through the contact etch resistance layer 160′ and reaches the top surface of the dielectric layer 154, and the contact openings CO1 and CO2 are completely open. At this third stage, the contact openings CO1 and CO2 reaches and exposes the metal salicide layers 142 and 144. In some embodiments, the third stage of the etch process may use a third etch recipe that has a third etch selectivity of silicon oxide to silicon nitride less than 1, such that the third stage of the etch process removes the contact etch resistance layer 160′ and the contact etch stop layer 153 at a faster etch rate than it removes the dielectric layer 154. And, the dielectric layer 154 may serve as an etch stop layer during the third stage of the etch process.

In some embodiments of the present disclosure, the third stage of the etch process may stop when the etch signal shows little or no silicon nitride (e.g., when an intensity of the material of the contact etch resistance layer 160′ of the etch signal ES is lower than a threshold intensity value Ir2, as shown later in FIG. 10). This indicates the etch stop time point that dielectric layer 154 is just exposed by the contact opening CO3. In some alternative embodiments of the present disclosure, the third stage of the etch process may be performed using time mode to allow the etching process to stop at a determined time after the second stage, such that the contact opening CO3 is etched through the contact etch resistance layer 160′ and exposing the dielectric layer 154.

The dielectric layer 154 exposed by the contact opening CO3 may be slightly consumed by the third stage of the etch process. For example, a first portion of a top surface of the dielectric layer 154 exposed by the contact opening CO3 is lowered than a second portion of the top surface of the dielectric layer 154 surrounding the first portion of the top surface of the dielectric layer 154. In some embodiments, the metal salicide layers 142 and 144 may remain substantially intact after the etch process since the metal salicide layers 142 and 144 has a higher etch resistance to the etch process than the dielectric layer 154, the contact etch resistance layer 160′, and the ILD layer 170.

Reference is made to FIG. 9. The contact openings CO1-CO3 are filled with one or more conductive materials. In some embodiments, the one or more conductive materials may include tungsten (W), cobalt, copper, titanium (Ti), titanium nitride (TiN), tantalum nitride (TaN), the like, or combinations thereof. A planarization process (e.g., CMP) may be subsequently performed to remove excess portions of the one or more conductive materials and to form a substantially planar surface, thereby forming plural contacts CT1-CT3 in the contact openings CO1-CO3.

The contacts CT1 and CT2 extend through the interlayer dielectric layer 170 and land on the source region 116 and the drain region 118, respectively. For example, the contacts CT1 and CT2 are in contact with the metal salicide layer 142 over the source region 116 and the contact region 119 and the metal salicide layer 144 over the drain region 118, respectively. Thus, the contacts CT1 and CT2 may serve as a source contact and a drain contact.

The contact CT3 extends through the interlayer dielectric layer 170 and the contact etch resistance layer 160′ and in contact with the top surface of the dielectric layer 150. The contact CT3 may serve as a field plate to adjust an electric field in the drift region 114 between the source region 116 and the drain region 118. In the context, the contact CT3 may be referred to as a contact field plate. In the present embodiments, the contact CT3 is spaced apart from the drift region 114 by the dielectric layer 154, the contact etch stop layer 153, and the salicide block layer 152. In some other embodiments, the contact etch stop layer 153 may be omitted. The contact CT3 may have a sidewall CT3S in contact with the contact etch resistance layer 160′ and a bottom surface CT3B free from coverage by the etch resistance layer 160′. The bottom surface CT3B of the contact CT3 and a bottom surface of the etch resistance layer 160′ may be in contact with the top surface of the dielectric layer 154. In some embodiments, the bottom surface CT3B of the contact CT3 is substantially aligned with the bottom surface of the contact etch resistance layer 160′.

After the formation of the contacts CT1-CT3, a metallization layer 200 is formed over the interlayer dielectric layer 170 and the contacts CT1-CT3. The metallization layer 200 may include metal features 212-216 connected to the contact field plate and a dielectric layer 220 surrounding the metal features 212-216. The metal features 212-216 may be metal lines extending horizontally in the dielectric layer 220.

FIG. 10 is an example signal diagram illustrating an etch signal ES for etch stop detection in accordance with some embodiments of the present disclosure. During the etch process, a gas inside a chamber of the etcher is detected as an etch signal ES (see FIG. 10), for example, by a etch detection system (e.g., gas concentration detectors). The etch detection system may be designed such that the etch signal ES may reveal some relevant species (such as the material of the contact etch resistance layer 160′ and the nitride layer 153 (e.g., silicon nitride)) and amounts of said species (e.g., silicon nitride) in the gas inside the chamber of the etcher.

The etch process includes introducing the gaseous reactant (i.e., the etchant gases) into the chamber and inducing chemical reaction through the interaction of the gaseous reactants and the materials to be removed. The chemical reaction yields by-product gas that can be easily removed from the chamber of the etcher. As the gas inside a chamber of the etcher includes the by-product gas therein, the etch signal ES may vary according to various by-product gases during the etch process. The etch detection system may be designed such that the etch signal ES may reveal some relevant species of the by-product gases and amounts of said species in the gas inside the chamber of the etcher. For example, in the present embodiments, the etch detection system is designed such that the etch signal ES may reveal the material of the contact etch resistance layer 160′ and the nitride layer 153 (e.g., silicon nitride)) and the amounts thereof.

With the etch signal ES, some stages of the contact etch process in FIGS. 6-8 may stop based on the intensity of the silicon nitride indicated by the etch signal ES. With reference to the contact etching processes in FIGS. 6-8, the first timing point S1 may correspond to an etch stop point of the first stage of the etch process in FIG. 6, the second timing point S2 may correspond to an etch stop point of the second stage of the etch process in FIG. 7, and the third timing point S3 may correspond to an etch stop point of the third stage of the etch process in FIG. 8.

For example, the second stage of the etch process in FIG. 7 may be stopped when the etch signal shows a large amount of silicon nitride (e.g., when an intensity of the material of the contact etch resistance layer 160′ indicated by the etch signal ES is higher than a threshold intensity value Ir1). The threshold value Ir1 may be 50% to 90% of the maximum intensity of silicon nitride indicated by the etch signal ES. This indicates the etch stop time point that the contact etch stop layer 153 are just exposed by the contact openings CO1 and CO2.

For example, the third stage of the etch process in FIG. 8 may be stopped when the etch signal ES shows little or no silicon nitride (e.g., when an intensity of the silicon nitride indicated by the etch signal ES is lower than a threshold value Ir2). The threshold value Ir2 may be 1% to 5% or less of the maximum intensity of silicon nitride indicated by the etch signal ES. This indicates that the third stage of the contact etch process in FIG. 8 may use a bottom surface of the contact etch resistance layer 160′ (or a top surface of the dielectric layer 154 below the contact etch resistance layer 160′) as an end point detection.

FIG. 11 illustrates a cross-sectional view of an intermediate stage in the manufacture of a semiconductor device in accordance with some embodiments of the present disclosure. Details of the present embodiments are similar to those illustrated in FIGS. 1-9, except that the first stage of the etch process is stopped when the contact etch resistance layer 160′ is exposed by the contact openings CO3 in the present embodiments. For example, the timing point S1′ in FIG. 10 may correspond to the etch stop point of the first stage of the etch process in FIG. 11. Other details of the present embodiments are similar to those illustrated in FIGS. 1-9, and therefore not repeated herein.

FIG. 12 illustrates a cross-sectional view of an intermediate stage in the manufacture of a semiconductor device in accordance with some embodiments of the present disclosure. Details of the present embodiments are similar to those illustrated in FIGS. 1-9, except that the contact openings CO1 and CO2 are fully open at the second stage of the etch process after the first stage of the etch process (referring to FIG. 6) in the present embodiments. For example, at the second stage of the etch process, while the contact opening CO3 is etched into a middle level in the contact etch resistance layer 160′, the contact openings CO1 and CO2 may extend through the dielectric layer 154 and the contact etch stop layer 153 and be stopped by the metal salicide layers 142 and 144 therebelow. Other details of the present embodiments are similar to those illustrated in FIGS. 1-9, and therefore not repeated herein.

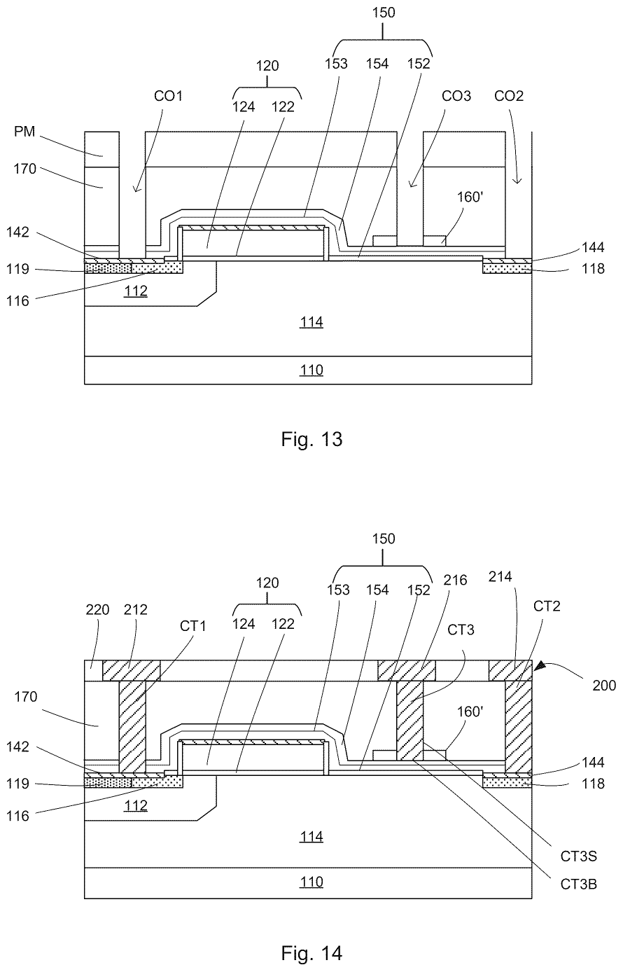

FIGS. 13-14 illustrate schematic cross-sectional views of intermediate stages in the manufacture of a semiconductor device in accordance with some embodiments of the present disclosure. Details of the present embodiments are similar to the embodiments of FIGS. 1-9, except that the contact opening CO3 may be etched without consuming the dielectric layer 154 therebelow. Thus, in FIG. 13, a first portion of a top surface of the dielectric layer 154 exposed by the contact opening CO3 is substantially level with a second portion of the top surface of the dielectric layer 154 surrounding the first portion of the top surface of the dielectric layer 154. And, in FIG. 14, the bottom surface CT3B of the contact CT3 and the bottom surface of the etch resistance layer 160′ are in contact with the top surface of the dielectric layer 154, in which the bottom surface CT3B of the contact CT3 is substantially level with the bottom surface of the contact etch resistance layer 160′.

In some embodiments of the present disclosure, by using the etch signal of the material of the contact etch resistance layer (e.g., silicon nitride) as the timing point for stopping the contact opening etching process, a height/bottom of the contact opening for the field plate (e.g., contact CT3) can be determined by a thickness of the multi-film dielectric layer 150 under the contact etch resistance layer. Through the configuration, the distance between a bottom of the contact field plate and the substrate surface can be controlled accurately. And, the height of the field plate can be well controlled.

Although the present invention has been described with reference to several exemplary embodiments, it is to be understood that the terms used are illustrative and exemplary rather than restrictive terms. Since the present invention can be embodied in various forms without departing from the spirit or substance of the invention, it should be understood that the above-described embodiments are not limited to any foregoing details, but are to be construed broadly within the spirit and scope defined by the appended claims. Therefore, all changes and modifications falling within the scope of the claims or their equivalents shall be covered by the appended claims.

What is claimed is:

1. A semiconductor device, comprising:
a semiconductor substrate having a source region, a drain region, a body region between the source region and the drain region, and a drift region between the body region and the drain region;
a gate structure at least over the body region of the semiconductor substrate;
a dielectric layer over the drift region of the semiconductor substrate and surrounding the gate structure;
an etch resistance layer over the drift region of the semiconductor substrate and in contact with a top surface of the dielectric layer, wherein the etch resistance layer comprises a material different from a material of the dielectric layer; and
a contact field plate over the drift region of the semiconductor substrate and the dielectric layer, wherein the contact field plate extends through the etch resistance layer and in contact with the top surface of the dielectric layer.

2. The semiconductor device of claim 1, wherein the dielectric layer comprises silicon oxide, and the etch resistance layer comprises silicon nitride.

3. The semiconductor device of claim 1, wherein the source region and the drain region are free from coverage by the etch resistance layer.

4. The semiconductor device of claim 1, wherein the gate structure is free from coverage by the etch resistance layer.

5. The semiconductor device of claim 1, wherein the contact field plate is spaced apart from the drift region of the semiconductor substrate by the dielectric layer.

6. The semiconductor device of claim 1, wherein the etch resistance layer is laterally aligned with the gate structure.

7. The semiconductor device of claim 1, wherein a sidewall of the contact field plate is in contact with the etch resistance layer.

8. The semiconductor device of claim 1, wherein a bottom surface of the contact field plate is lower than a top surface of the gate structure.

9. The semiconductor device of claim 1, wherein the dielectric layer extends beyond opposite sidewalls of the etch resistance layer.

10. The semiconductor device of claim 1, wherein the etch resistance layer has a thickness in a range from 500 angstroms to 2000 angstroms.

11. A semiconductor device, comprising:
a semiconductor substrate having a source region, a drain region, and a drift region between the body region and the drain region and near the drain region;
a gate structure over a region of the semiconductor substrate between the source region and the drain region;
an etch resistance layer over the drift region of the semiconductor substrate, wherein the source region and the drain region are free from coverage by the etch resistance layer;
an interlayer dielectric layer over the gate structure and the etch resistance layer, wherein the interlayer dielectric layer comprises a material different from a material of the etch resistance layer;
a contact field plate over and spaced apart from the drift region of the semiconductor substrate, wherein the contact field plate extends through the interlayer dielectric layer and the etch resistance layer, and the contact field plate has a bottom surface free from coverage by the etch resistance layer; and
a source contact extends through the interlayer dielectric layer and lands on the source region, wherein the source contact is spaced apart from the etch resistance layer.

12. The semiconductor device of claim 11, further comprising:
a dielectric layer in contact with the bottom surface of the contact field plate and
a bottom surface of the etch resistance layer.

13. The semiconductor device of claim 12, wherein the interlayer dielectric layer comprises silicon oxide, the etch resistance layer comprises silicon nitride, and the dielectric layer comprises silicon oxide.

14. The semiconductor device of claim 11, wherein the bottom surface of the contact field plate is higher than a bottom surface of the source contact.

15. The semiconductor device of claim 11, wherein a lower portion of a sidewall of the contact field plate is in contact with the etch resistance layer, and an upper portion of the contact field plate is in contact with the interlayer dielectric layer.

16. The semiconductor device of claim 11, further comprising:
a metallization layer over the interlayer dielectric layer and the contact field plate, wherein the metallization layer comprises a metal feature connected to the contact field plate.

17. The semiconductor device of claim 11, wherein the bottom surface of the contact field plate is lower than a bottom surface of the etch resistance layer.

18. A method for manufacturing a semiconductor device, comprising:
forming a drift region in a semiconductor substrate;
forming a gate structure over the semiconductor substrate;
forming a source region and a drain region in the semiconductor substrate;
depositing a dielectric layer over the gate structure and the semiconductor substrate;
forming an etch resistance layer over the dielectric layer;
depositing an interlayer dielectric layer over the etch resistance layer and the dielectric layer;
performing an etch process to etch a first contact opening through the interlayer dielectric layer and the etch resistance layer, wherein the first contact opening exposes a top surface of the dielectric layer; and
forming a contact field plate in the first contact opening.

19. The method of claim 18, wherein forming the contact field plate is performed such that the contact field plate is in contact with the top surface of the dielectric layer.

20. The method of claim 18, wherein the etch resistance layer comprises silicon nitride.

21. The method of claim 18, further comprising:
depositing a contact etch stop layer over the source region and the drain region prior to depositing the dielectric layer, wherein the etch process is further performed to etch a second contact opening through the interlayer dielectric layer, the dielectric layer, and the contact etch stop layer over the source region, and the method further comprises:
forming a source contact in the second contact opening.

22. The method of claim 21, wherein forming the etch resistance layer is performed such that the etch resistance layer has a thickness greater than that of the contact etch stop layer.

23. The method of claim 21, wherein performing the etch process comprises:
performing a first etch stage to etching the first contact opening and the second contact opening in the interlayer dielectric layer;
performing a second etch stage to deepen the first contact opening and the second contact opening until the contact etch stop layer is exposed by the second contact opening; and
performing a third etch stage to deepen the first contact opening and the second contact opening until the dielectric layer is exposed by the first contact opening, wherein the second contact opening extends through the contact etch stop layer.

24. The method of claim 23, wherein the second etch stage has an etch selectivity of silicon oxide to silicon nitride greater than 1.

25. The method of claim 23, wherein the first etch stage has a first etch selectivity of silicon oxide to silicon nitride, the second etch stage has a second etch selectivity of silicon oxide to silicon nitride, and the second etch selectivity is greater than the first etch selectivity.

26. The method of claim 23, wherein the second etch stage has an etch selectivity of silicon oxide to silicon nitride greater than 1.

27. The method of claim 23, wherein performing the etch process comprises:
stopping the third etch stage when an etch signal of silicon nitride is less than a threshold value.
